(19) United States
(12) Patent Application Publication
(10) Pub. No.: US 2022/0404207 A1
(43) Pub. Date: Dec. 22, 2022

(54) SURFACE-MOUNTED INFRARED DETECTOR

(71) Applicant: NIPPON CERAMIC CO., LTD., Tottori-shi, Tottori (JP)

(72) Inventors: Eiki FUJIWARA, Tottori-shi (JP); Yoichi MURATA, Tottori-shi (JP); Kuniyasu ENOKI, Tottori-shi (JP); Yukari SUGII, Tottori-shi (JP)

(73) Assignee: NIPPON CERAMIC CO., LTD., Tottori-shi, Tottori (JP)

(21) Appl. No.: 17/773,449

(22) PCT Filed: Nov. 5, 2019
(86) PCT No.: PCT/JP2019/043246

§ 371 Date: Apr. 29, 2022

(51) Int. Cl. G01J 5/04

(52) U.S. Cl. CPC G01J 5/048; G01J 5/34

(57) ABSTRACT

An infrared detector capable of surface-mounting and excellent in electromagnetic wave resistance performance includes: a metal can-type infrared detector configured by disposing a pyroelectric photoelectric conversion element inside a metal package including a plurality of leads; and an insulating spacer made of an electric insulating material and equipped with a one or more through-holes through which the plurality of leads can penetrate. The plurality of leads of the metal can-type infrared detector are inserted into the through-hole from an upper surface side of the insulating spacer and a tip side of the lead is bent toward an outer periphery of the insulating spacer on a lower surface of the insulating spacer, whereby the metal can-type infrared detector is mechanically fixed to the insulating spacer.

### TECHNICAL FIELD

The present invention relates to a surface-mounted infrared detector with a pyroelectric photoelectric conversion element.

### BACKGROUND ART

A pyroelectric infrared detector used for detection of movement of a human body or the like has a configuration in which a pyroelectric photoelectric conversion element is housed inside a package having an infrared transmissive window through which infrared rays transmit. Since the pyroelectric photoelectric conversion element is a circuit element of high impedance and susceptible to electromagnetic noise, a package so-called can-type package made of metal is widely used as a package used in a infrared detector. A circuit connected to the pyroelectric photoelectric conversion element and performing impedance conversion is provided in the package in many cases, and further, if necessary, various signal processing circuits may also be provided in the package. A cylindrical package of TO-5 type defined by JEDEC is often used as a metal can-type package. This type of metal can-type package consists of a disc-shaped base and a case (also referred to as a cap) provided so as to cover one surface of the base. A plurality of leads extend perpendicularly to the base from the other surface of the base. In the following description, a pyroelectric infrared detector using a metal can-type package is referred to as a metal can-type infrared detector.

When mounting the metal can-type infrared detector on a wiring board or a circuit board, the leads are respectively inserted to a plurality of through-holes formed in the wiring board, and then the tip side of the lead coming out from the through-hole is soldered to a circuit pattern of the wiring board. Thus the infrared detector will be mechanically and electrically bonded to the wiring board. A Soldering iron or flow soldering equipment is used for soldering. The metal can-type infrared detector is excellent in electromagnetic wave resistance characteristics, because the upper surface, the lower surface and the side surface thereof are covered with the metal case and the base expect for the portion of the infrared transmissive window and the portion of hermetic seals provided in the base for leading out the leads. However, since this kind of metal can-type infrared detector requires manual soldering by a soldering iron or use of flow soldering equipment when the detector is mounted on a wiring board, it is impossible to perform mounting using a surface mounting machine and solder-bonding using a reflow furnace.

Patent Literatures 1 to 3 disclose surface-mounted infrared detectors which can be surface-mounted on a wiring board or the like without using a lead and can be easily miniaturized. In the surface-mounted infrared detectors disclosed in Patent Literatures 1 to 3, since electrode patterns or terminals for the purpose of electrical bonding with a wiring board or the like are provided on the lower surface or the side surface thereof, the detectors can be mounted on the wiring board by using a surface mounting machine and subjected to solder-bonding using a reflow furnace.

### CITATION LIST

### Patent Literature

Patent Literature 1: JP 2013-44560A
Patent Literature 2: JP 2014-35238A
Patent Literature 3: JP 2007-288168A

### SUMMARY OF THE INVENTION

### Technical Problem

In the surface-mounted infrared detectors disclosed in Patent Literatures 1 to 3, the lower surface or side surface of the detector is composed of an electrically insulating material such as resin, in order to provide a power supply terminal and a signal output terminal. Since the surfaces composed of these electrically insulating materials do not have ability to shield electromagnetic waves, the high impedance circuit portion inside the detector is susceptible to electromagnetic waves from the outside through these surfaces. As a result, the electromagnetic wave resistance characteristics of the infrared detector are lowered, and erroneous detection or the like is likely to occur, causing false alarms or the like in a product equipped with this infrared detector.

The present invention is to solve the above problems. The object of the present invention is provide a surface-mounted infrared detector which is excellent in electromagnetic wave resistance characteristics and capable of surface-mounting using a surface mounting machine and reflow soldering while maintaining the performance of the existing metal can-type infrared detector.

### Solution to Problem

The surface-mounted infrared detector according to the present invention comprises: a metal can-type infrared detector configured by disposing a pyroelectric photoelectric conversion element inside a metal package including a plurality of leads; and an insulating spacer made of an electric insulating material and equipped with a one or more through-holes through which the plurality of leads can penetrate, wherein the plurality of leads are inserted into the through-hole from an upper surface side of the insulating spacer and a tip side of the lead is bent toward an outer periphery of the insulating spacer on a lower surface of the insulating spacer, whereby the metal can-type infrared detector is mechanically fixed to the insulating spacer.

In the present invention, an existing pyroelectric type infrared detector, or a metal can-type infrared detector, using a metal package which has a plurality of leads and encloses a pyroelectric photoelectric conversion element is used, the leads of the metal package are inserted from the upper surface side of the insulating spacer to the through-hole provided in the insulating spacer, and, on the lower surface side of the insulating spacer, the tip end of the lead is bent along the lower surface of the insulating spacer. As a result, the metal can-type infrared detector is mechanically fixed to the insulating spacer, and, on the lower surface of the insulating spacer, the lead is exposed along the lower surface. It becomes possible to perform surface-mounting on a wiring board or the like by using the exposed portion of the lead as a terminal for mechanical and electrical connection.

### Advantageous Effects of Invention

According to the present invention, a surface-mounted infrared detector capable of performing surface-mounting using a surface mounting machine and reflow furnace can be obtained through a simple manufacturing process, while maintaining a high electromagnetic wave resistance characteristics by using a metal package.

### BRIEF DESCRIPTION OF DRAWINGS

FIG. 1 is an assembly perspective view showing a surface-mounted infrared detector according to one embodiment of the present invention.

FIG. 2 is a cross-sectional view showing the configuration of an insulating spacer.

FIG. 3 is a completed perspective view of the surface-mounted infrared detector according to the embodiment.

FIG. 4 is a perspective view of the surface-mounted infrared detector shown in FIG. 3, seen from the lower surface side.

FIG. 5 is a perspective view of the insulating spacer having one through-hole.

### DESCRIPTION OF EMBODIMENTS

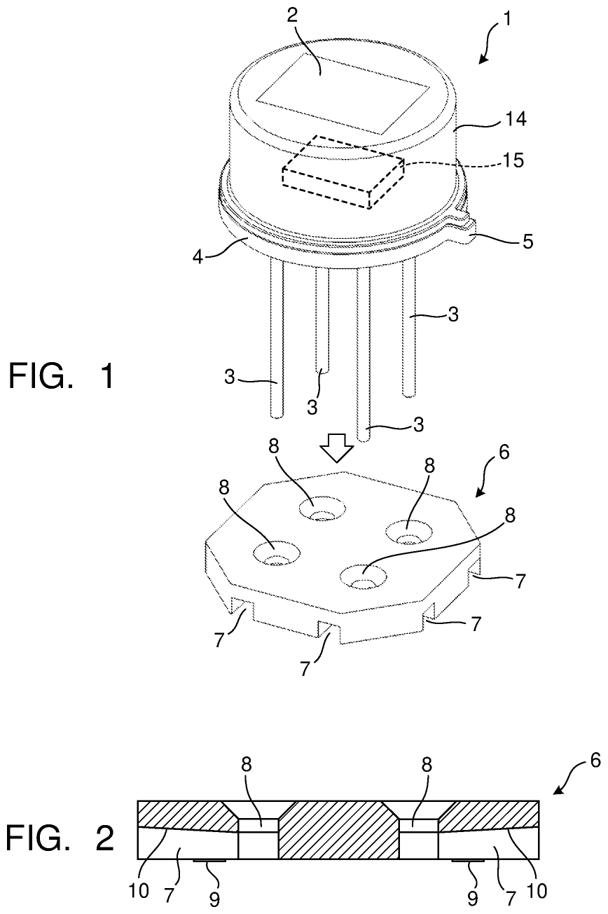

Next, embodiments of the present invention will be described with reference to the drawings. As shown in FIG. 1, the surface-mounted infrared detector according to one embodiment of the present invention is constituted by metal can-type infrared detector 1 and insulating spacer 6. This surface-mounted infrared detector is suitable for performing surface-mounting on a wiring board by, for example, reflow soldering or the like.

Metal can-type infrared detector 1 is made of an existing metal can-type package. The Metal can-type package comprises: disc-shaped base 4; and case 14 of a cylindrical shape so as to cover one of the sides of base 4. Optical filter 2 as an infrared transmissive window which allows infrared rays to penetrate the interior of the package is provided in the upper surface of case 14. Pyroelectric photoelectric conversion element 15 is provided inside the package in a manner facing optical filter 2, so that the infrared rays transmitted through optical filter 2 are incident. An electric circuit such as an impedance conversion circuit for connecting pyroelectric photoelectric conversion element 15 to an external circuit may be provided inside the package. As the metal can-type package, for example, a TO-5 package defined by JEDEC is used, but a TO-39 package or other size package may be used. From base 4, a plurality of leads 3 extend perpendicularly to base 4. Four leads 3 are provided in the example shown here. Leads 3 are used to electrically connect metal can-type infrared detector 1 to an external circuit. Further, tab 5 used for performing identification of leads 3 is formed on the outer periphery of the package.

Insulating spacer 6 is a plate-like member, and is composed of an electrically insulating material. It is preferable that insulating spacer 6 has heat resistance equal to or higher than the melting point of solder, for example, heat resistance to withstand heat of 260° C. or higher so as to withstand reflow soldering. Insulating spacer 8 in the illustrated has an octagonal outer shape. A plurality of through-holes 8 capable of receiving leads 3 respectively corresponding to leads 3 of metal can-type infrared detector 1 are formed in insulating spacer 6. On the upper surface side of insulating spacer 6, each through-hole 8 is formed in a tapered shape so as to easily receive lead 3. On the other hand, a groove-shaped recess 7 extending linearly toward the outer peripheral portion of insulating spacer 6 from through-hole 8 is formed in the lower surface of insulating spacer 6. In the present embodiment, for each through-hole 8, two recesses 7 are provided in insulating spacer 6 so that their extending directions are different about 90°.

Recess 7 is configured so that, when lead 3 has been inserted into through-hole 8 from the upper surface side of insulating spacer 6 and lead 3 which has passed thorough through-hole 8 is bent along recess 7, recess 7 can at least partially receive the bent portion of lead 3. Bottom surface 10 of recess 7 may be formed so as to be inclined in a direction toward the upper surface of insulating spacer 6 from a position of connection to through-hole 8, so that lead 3 having passed through through-hole 8 is bent by 90° or more when lead 3 is bent along recess 7. FIG. 2 is a cross-sectional view of insulating spacer 6. The inclination angle of bottom surface 10, i.e., an angle formed between the extension of bottom surface 10 and the upper surface of insulating spacer 6, is preferably set to 0° or more and 10° or less, and set to, for example, 5°. Further, on the lower surface of insulating spacer 6, a plurality of standoffs 9 are provided at a position where recess 7 is not formed.

The surface-mounted infrared detector according to the present embodiment is assembled by inserting lead 3 of metal can-type infrared detector 1 into through-hole 8 of insulating spacer 6 until base 4 comes into contact with the upper surface of insulating spacer 6, and bending, in this state, the tip side of lead 3 inserted into through-hole 8 along recess 7. The bending angle of lead 3 is, for example, 80° or more. The bending angle in this Description is expressed by an angle how much the angle is bent from the straight state before bending at the folding position. By setting the inclination angle to bottom surface 10 of recess 7 as described above, it is possible to form the bending angle of 90° or more. Further, by providing the inclination angle on bottom surface 10, it can be easily performed that lead 3 is folded to temporally exceed 90° in consideration of spring back when bending lead 3, and then the final bending angle of 90° is achieved.

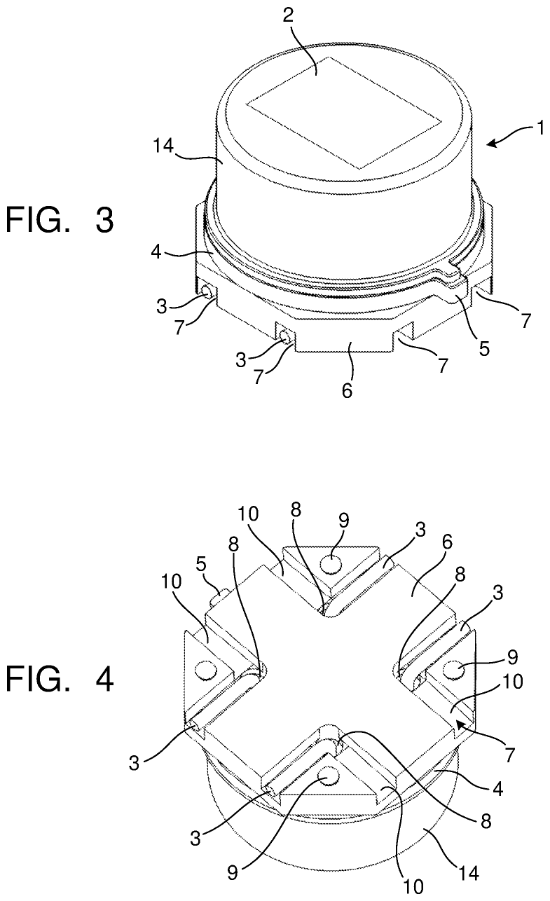

In this embodiment, since lead 3 in a state where base 4 is in contact with the upper surface of insulating spacer 6 is bent in the outer circumferential direction of insulating spacer 6, metal can-type infrared detector 1 is mechanically fixed to insulating spacer 6. In order to prevent the tip end of lead 3 which is bent along recess 7 at this time protrudes from the outer periphery of insulating spacer 6 when using long lead 3, it is preferable to cut and align lead 3 in advance to a predetermined length. FIGS. 3 and 4 show the surface-mounted infrared detector of the present embodiment obtained by mechanically fixing metal can-type infrared detector 1 to insulating spacer 6. As shown, the tip side of lead 3 is bent along recess 7 and exposed linearly on the lower surface of insulating spacer 6. By using this exposed portion of lead 3 as a terminal for mechanical and electrical connection, it is possible to surface-mount the surface-mounted infrared detector of the present embodiment on a substrate such as a wiring board.

Standoff 9 is provided so as to slightly project from the lower surface of insulating spacer 6 than lead 3 when lead 3 protruding from through-hole 8 is bent at a right angle, i.e., 90°. By providing standoff 9 in this manner, standoff 9 always protrudes from the lower surface of insulating spacer 6 than lead 3 if the bending angle of lead 3 is 90° or more. Therefore, in this case, when the lower surface of insulating spacer 6 is surface-mounted on the wiring board, the mounting parallelism of the surface-mounted infrared detector is independent of the bending angle of lead 3.

In the present embodiment, by forming insulating spacer 6 in a symmetrical shape, insulating spacer 6 can be installed regardless of the direction of the insulating spacer 6 to improve productivity when inserting the plurality of leads 3 of metal can-type infrared detector 1 into the plurality of through holes 8, respectively. When surface-mounting the assembled surface-mounted infrared detector on a wiring board or the like, it is possible to determine the orientation at the time of mounting based on tab 5 provided in the package of metal can-type infrared detector 1. The position of tab 5 can be visually confirmed and the direction can be also identified by a surface mounting machine. Further, since a plurality of recesses 7 are provided for each through-hole 8, the bending direction at the time of bending lead 3 is not limited to one direction. It is also possible to select the bending direction of lead 3 according to the wiring pattern in the substrate on which the surface-mounted infrared detector is mounted.

As described above, since existing metal can-type infrared detector 1 and insulating spacer 6 are combined, the surface-mounted infrared detector of the present embodiment can be mounted on a wiring board or the like by a surface mounting machine, and then mechanically and electrically bonded to the wiring board or the like by solder using a reflow furnace. When using reflow soldering, pyroelectric photoelectric conversion element 15 provided in metal can-type infrared detector 1 is required to have a higher Curie temperature than the temperature at the time of reflow soldering. As an example, pyroelectric photoelectric conversion element 15 preferably has a Curie temperature of 260° C. or higher.

Metal can-type infrared detector 1 in the above embodiment includes four leads 3. When the number of leads 3 is increased or decreased, the number of through-holes 8 of insulating spacer 6 is matched with the number of leads 3, so that the surface-mounted infrared detector can be assembled regardless of the number of leads 3. By using insulation spacer 6 matched with the shape and specifications of existing metal can-type infrared detector 1, surface-mounting can be performed regardless of the type of metal can-type infrared detector 1.

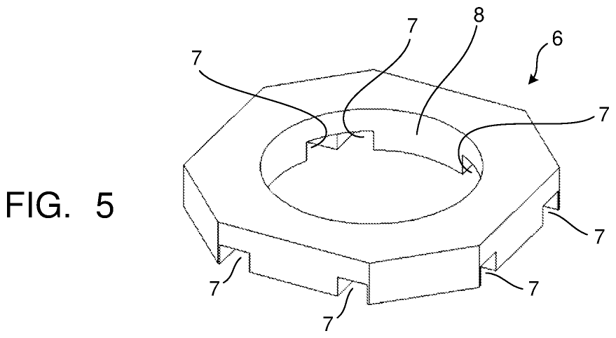

In the above description, the same number of through-holes 8 as the number of leads 3 are provided in insulating spacer 6, and one lead 3 is passed through one through-hole 8, but the configuration of insulating spacer 6 is not limited thereto. As shown in FIG. 5, through-hole 8 of a size capable of receiving all of the plurality of leads 3 of metal can-type infrared detector 1 may be provided only one in insulating spacer 6. In this case, the size, for example, the diameter, of through-hole 8 must be smaller than base 4 of metal can-type infrared detector 1 so that the upper surface of insulating spacer 6 at the portion of the outer periphery of through-hole 8 is in contact with base 4 in a state in which all leads 3 pass through through-hole 8. Similarly to those described above, recesses 7 are provided on the lower surface of insulating spacer 6. The tip side of each lead 3 passing through through-hole 8 is bent along recess 7 toward the outer periphery of insulating spacer 6, so that metal can-type infrared detector 1 can be mechanically fixed to insulating spacer 6 without depending on the number of leads 3, and the surface-mounted infrared detector can be constituted.

According to the present invention, since the components required to constitute the surface-mounted infrared detector is only existing metal can-type infrared detector 1 and insulating spacer 6, it is possible to provide an infrared detector which is excellent in economy and possible to perform surface-mounting, without changing the electrical characteristics. Therefore, the surface-mounted infrared detector according to the present invention can be used not only in lighting equipment having a human body detection function but also in a wide range of fields such as crime prevention equipment, fire detectors, and the like.

### REFERENCE SIGNS LIST

1 Metal can-type infrared detector;
2 Optical filter;
3 Lead;
4 Base;
5 Tab;
6 Insulating spacer;
7 Recess;
8 Through-hole
9 Standoff;
10 Bottom surface;
15 Pyroelectric photoelectric conversion element.

1-7. (canceled)

8. A pyroelectric infrared detector capable of surface-mounting, comprising:
a metal can-type pyroelectric infrared detector configured by disposing a pyroelectric element inside a metal package including a plurality of leads, the pyroelectric element having a Curie point of 260° C. or higher; and
an insulating spacer made of an electric insulating material and equipped with a one or more through-holes through which the plurality of leads can penetrate,
wherein the plurality of leads are inserted into the through-hole from an upper surface side of the insulating spacer and a tip side of the lead is bent toward an outer periphery of the insulating spacer on a lower surface of the insulating spacer, whereby the metal can-type pyroelectric infrared detector is mechanically fixed to the insulating spacer.

9. The pyroelectric infrared detector according to claim 8, wherein, in the lower surface of the insulating spacer, a recess of a groove shape extending linearly toward the outer periphery of the insulating spacer from the through-hole is provided for each through-hole, and the lead is bent along the recess, and
wherein a bottom surface of the recess is inclined at an inclination angle of more than 0° and 10° or less so as to approach the upper surface of the insulating spacer from a connection position to the through-hole toward the outer periphery of the insulating spacer.

10. The pyroelectric infrared detector according to claim 8, wherein the tip side of the lead is bent at a bending angle of 80° or more.

11. The pyroelectric infrared detector according to claim 9, wherein the tip side of the lead is bent at a bending angle of 80° or more.
